(19) United States
(12) Patent Application Publication
(10) Pub. No.: US 2026/0190403 A1
(43) Pub. Date: Jul. 2, 2026

(54) SEMICONDUCTOR DEVICE WITH BOTTOM CHANNEL ISOLATION, AND METHOD FOR FABRICATING THE SAME

(71) Applicant: TAIWAN SEMICONDUCTOR MANUFACTURING COMPANY, LTD., Hsinchu (TW)

(72) Inventors: Tsung-Han CHUANG, Hsinchu (TW); Jung-Hung CHANG, Hsinchu (TW); Shih-Cheng CHEN, Hsinchu (TW); Wen-Ting LAN, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 19/003,796

(22) Filed: Dec. 27, 2024

(51) Int. Cl. H10D 62/10; H10D 30/00; H10D 30/01; H10D 84/01; H10D 84/83

(52) U.S. Cl. CPC H10D 62/116; H10D 30/0191; H10D 30/502; H10D 62/121; H10D 84/0133; H10D 84/0151; H10D 84/8311; H10D 84/8312; H10D 84/832

(57) ABSTRACT

A method is provided for fabricating a semiconductor device. A sacrificial layer is formed over a semiconductor substrate. A fin feature and source/drain spaces are formed over the sacrificial layer. A part of the sacrificial layer is exposed in each of the source/drain spaces. Sacrificial features are formed in the source/drain spaces. Source/drain features are formed over the sacrificial features in the source/drain spaces. The sacrificial layer and the sacrificial features are removed to form air-isolation features under the source/drain features, and an air-gap layer is formed in spatial communication with and under the air-isolation features. A gate feature is formed in the fin feature.

### BACKGROUND

The semiconductor integrated circuit (IC) industry has over the past decades experienced tremendous advancements and is still experiencing vigorous development. With the dramatic advances in IC design, new generations of ICs have smaller and more complex structures. Gate-all-around (GAA) devices (e.g., nanosheet transistors, nanorod transistors, nanowire transistors, etc.) have been developed to have a stacked channel structure surrounded by a gate structure, so as to increase the effective channel width in a transistor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides sectional views illustrating different types of gate-all-around (GAA) transistors in accordance with a first embodiment.

FIG. 2 is a top view illustrating a hybrid cell scheme in terms of effective channel width in accordance with the first embodiment.

FIG. 3 is a sectional view illustrating GAA transistors in the hybrid cell scheme in accordance with a second embodiment.

FIG. 4 is a top view illustrating the hybrid cell scheme in accordance with the second embodiment.

FIG. 5 is a sectional view illustrating GAA transistors in the hybrid cell scheme in accordance with a third embodiment.

FIG. 6 is a sectional view illustrating p-type GAA transistors in the hybrid cell scheme in accordance with a fourth embodiment.

FIG. 7 is a sectional view illustrating n-type GAA transistors in the hybrid cell scheme in accordance with the fourth embodiment.

FIG. 8 is a sectional view illustrating GAA transistors with mixed p-type source/drain and n-type source/drain in the hybrid cell scheme in accordance with the fourth embodiment.

FIG. 9 is a flow chart illustrating a method of fabricating GAA transistors in accordance with the fourth embodiment.

FIGS. 10 through 21 are sectional views illustrating intermediate structures formed during the fabrication of the GAA transistors in accordance with the fourth embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

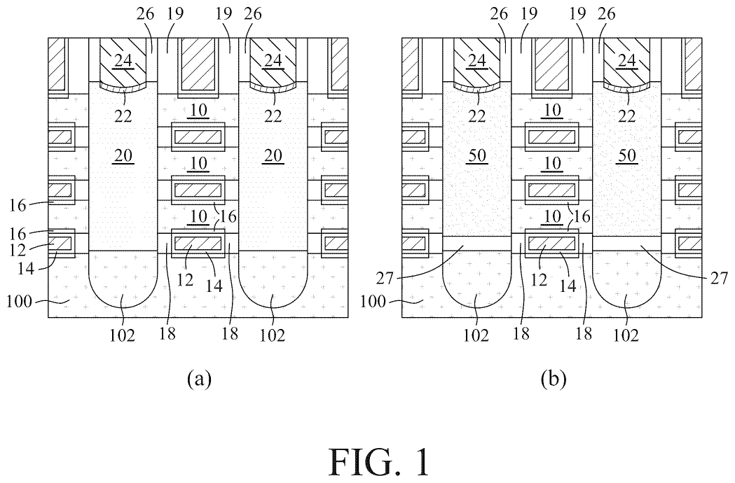

FIG. 1 illustrates sectional views of semiconductor devices formed over a semiconductor substrate 100 in accordance with a first embodiment. The semiconductor substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The semiconductor substrate 100 may be made of a suitable semiconductor material, such as silicon or the like. In some embodiments, the semiconductor substrate 100 is a silicon wafer; and in other embodiments, the semiconductor substrate 100 is made of a compound semiconductor such as silicon carbide, gallium arsenide, indium arsenide, indium phosphide or other suitable materials. In still other embodiments, the semiconductor substrate 100 is made of an alloy semiconductor such as GaAsP, AlInAs, AlGaAs, GaInAs, GaInP, GaInAsP or other suitable materials.

In some embodiments, the semiconductor substrate 100 includes various p-type doped regions and/or n-type doped regions, such as p-type wells, n-type wells, p-type source/drain features and/or n-type source/drain features, formed by a suitable process such as ion implantation, thermal diffusion, a combination thereof, or the like. In some embodiments, the semiconductor substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The semiconductor substrate 100 may include lateral isolation features (e.g., shallow trench isolation (STI)) configured to separate various functional elements formed on and/or in the semiconductor substrate 100.

In the illustrative embodiment, the semiconductor substrate 100 has a pair of semiconductor features 102 formed therein, and each of the semiconductor devices is exemplified as a gate-all-around (GAA) transistor that includes a channel feature, a gate feature, and a pair of source/drain features 20, 50 that are disposed respectively on the semiconductor features 102. In accordance with some embodiments, the semiconductor features 102 may include either the same material as the semiconductor substrate 100 or different materials, and may be formed during the fabrication of the semiconductor devices. In accordance with some embodiments, the semiconductor features 102 may include silicon, other suitable materials, or any combination thereof. In accordance with some embodiments, the semiconductor features 102 may be omitted, and the source/drain features 20, 50 are formed directly on the semiconductor substrate 100. In part (a) of FIG. 1, the semiconductor device is exemplified as a p-type GAA transistor, and the source/drain features 20 are of p-type, while in part (b) of FIG. 1, the semiconductor device is exemplified as an n-type GAA transistor, and the source/drain features 50 are of n-type. The channel feature includes a plurality of semiconductor sheets that are spaced apart from each other in a vertical direction perpendicular to a surface of the semiconductor substrate 100, and that serve as channel layers 10 of the GAA transistor. In accordance with some embodiments, the channel layers 10 may include, for example, p-doped silicon, n-doped silicon, other suitable materials, or any combination thereof, depending on what type of transistor the GAA transistor is. The gate feature includes a gate electrode 12 that surrounds each of the channel layers 10, and a gate dielectric 14 disposed between the gate electrode 12 and the channel layers 10. In accordance with some embodiments, the gate electrode 12 may include, for example, Cu, Ti, TiN, W, Al, Co, Ru, other suitable materials, or any combination thereof, and the gate dielectric 14 may include, for example, SiO₂, SiN, SiCN, SiCON, SiCO, AlO, HfO, high-k materials, other suitable materials, or any combination thereof. The gate electrode 12 includes a plurality of electrode sections that are alternately stacked with the channel layers 10. Disposed between the gate dielectric 14 and the channel layers 10 are interfacial layers 16, which may include materials such as silicon dioxide for enhancing adhesion between the gate dielectric 14 and the channel layers 10. In accordance with some embodiments, p-type source/drain features 20 may include, for example, SiGe doped with boron, other suitable materials, or any combination thereof. In accordance with some embodiments, n-type source/drain features 50 may include, for example, silicon doped with phosphorus or arsenic, other suitable materials, or any combination thereof. In accordance with some embodiments, the n-type GAA transistor may further include isolation layers 27 disposed between the semiconductor features 102 and the source/drain features 50 for preventing n-type dopants from diffusing into the semiconductor features 102 and the semiconductor substrate 100, which may result in current leakage. In accordance with some embodiments, the isolation layers 27 may include, for example, silicon nitride, other suitable materials, or any combination thereof. The source/drain features 20, 50 are disposed adjacent and connected to each of the channel layers 10 respectively at opposite ends of the channel feature. For each of the electrode sections of the gate electrode 12, a pair of inner spacers 18 are disposed at opposite sides of the electrode section, and each of the inner spacers 18 is disposed between the electrode section and a respective one of the source/drain features 20, 50. In accordance with some embodiments, the inner spacers 18 may include, for example, SiO₂, SiC, SiN, SiCN, SiOC, SiON, SiCON, other suitable materials, or any combination thereof. A pair of source/drain contacts 24 are disposed over the source/drain features 20, 50. In accordance with some embodiments, each of the source/drain contacts 24 may include a barrier layer (not shown) and an electrode body. The electrode body may include, for example, Co, W, Ru, Cu, Al, Mo, Ti, Ni, Au, Pt, Pd, other suitable conductive materials, or any combination thereof. The barrier layer is disposed to prevent metal elements in the electrode body from diffusing into surrounding dielectrics, and may include, for example, Ta, TaN, Ti, TiN, other suitable materials, or any combination thereof. In some embodiments, the barrier layer may be omitted. A silicide layer 22 is disposed between the source/drain features 20 and the source/drain contacts 24 for improving the attachment of the source/drain contacts 24 to the source/drain features 20, 50, and for reducing contact resistance between the source/drain features 20, 50 and the source/drain contacts 24. In accordance with some embodiments, the silicide layer 22 may include, for example, NiSi, TiSi, TiNiSi, TiSiGe, NiSiGe, TiNiSiGe, RuSi, CoSi, MoSi, PtSi, TaSi, WSi, CrSi, ZrSi, other suitable materials, or any combination thereof. A pair of top spacers 19 are disposed at opposite sides of a top section of the gate electrode 12, which is disposed at a top one of the channel layers 10. Each of the top spacers 19 is disposed between the top section of the gate electrode 12 and a respective one of the source/drain contacts 24. For each of the top spacers 19, a dielectric layer 26 is disposed between the top spacer 19 and a corresponding one of the source/drain contacts 24. The dielectric layers 26 and the top spacers 19 electrically isolate the gate electrode 12 from the source/drain contacts 24, and thus prevent current leakage therebetween. In accordance with some embodiments, the top spacers 19 may include, for example, SiO₂, SiC, SiN, SiCN, SiOC, SiON, SiCON, other suitable materials, or any combination thereof. In accordance with some embodiments, the dielectric layers 26 may include, for example, SiC, SiN, SiCN, SiOC, SiON, SiCON, other suitable materials, or any combination thereof.

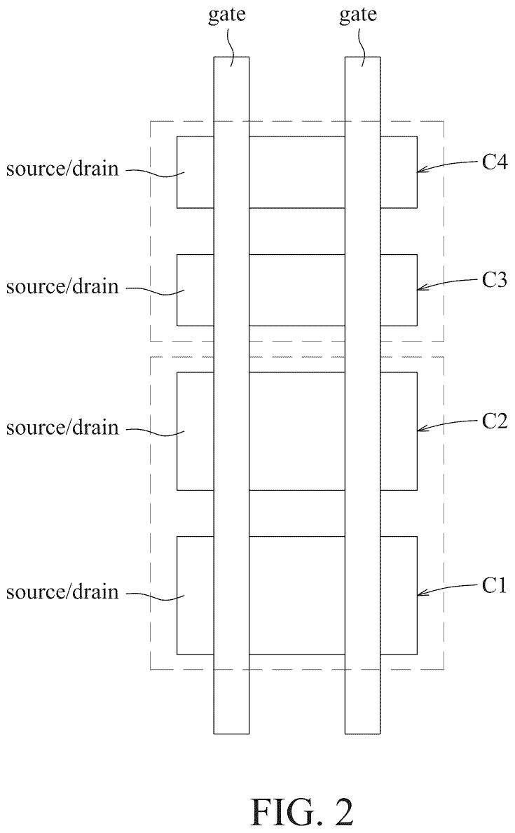

Further referring to FIG. 2, a top view is provided to illustrate an exemplary hybrid cell scheme in terms of effective channel width in accordance with the first embodiment. Transistor cells C1, C2, C3 and C4 are exemplified to have the same sectional structure as illustrated in FIG. 1. In the illustrative embodiment, the transistor cells C1, C2 are configured to have large ON-current for better speed performance, and the transistor cells C3, C4 are configured to have small ON-current for better power efficiency, so the transistor cells C1, C2 need larger effective channel widths than the transistor cells C3, C4. In order to meet this requirement, the transistor cells C1, C2 are made to have greater physical widths (corresponding to wider source/drain regions) to achieve greater effective channel widths, and the transistor cells C3, C4 are made to have smaller physical widths (corresponding to narrower source/drain regions) to achieve smaller effective channel widths.

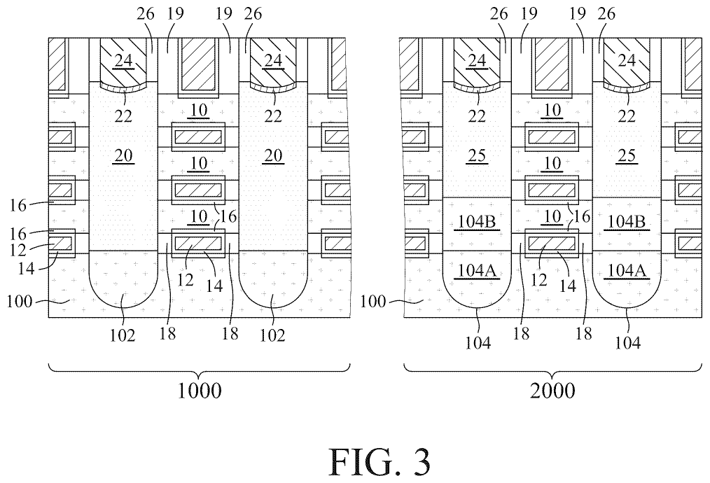

FIG. 3 illustrates sectional views of semiconductor devices formed over a semiconductor substrate 100 in accordance with a second embodiment, where the semiconductor devices are exemplified as p-type GAA transistors, but this disclosure is not limited in this respect. In a first circuit region 1000, the exemplary GAA transistor (referred to as a first GAA transistor hereinafter) has the same structure as shown in part (a) of FIG. 1, so details thereof are not repeated for the sake of brevity. In a second circuit region 2000, the exemplary GAA transistor (referred to as a second GAA transistor) is similar to the first GAA transistor, and differs in that the second GAA transistor includes a pair of semiconductor features 104 formed in the semiconductor substrate 100, and a pair of source/drain features 25 respectively disposed over the semiconductor features 104. A total number of the channel layers 10 of the first GAA transistor is the same as a total number of the channel layers 10 of the second GAA transistor. Each of the semiconductor features 104 includes a first portion 104A that has the same thickness (along a vertical direction that is perpendicular to a surface of the semiconductor substrate 100 from the perspective in FIG. 3) as the semiconductor features 102 of the first GAA transistor, and a second portion 104B formed over the first portion 104A. In practice, the first portions 104A of the semiconductor features 104 may be formed simultaneously with the semiconductor features 102, and then, the semiconductor features 102 are masked, followed by growing the second portions 104B of the semiconductor features 104 over the first portions 140A. In the illustrative embodiment, the semiconductor features 104 have a thickness greater than a thickness of the semiconductor features 102, and are respectively connected to opposite sides of a bottom one of the channel layers 10, thereby isolating the source/drain features 25 from the bottom one of the channel layers 10. As a result, a number of the channel layers 10 that the source/drain features 25 are connected to is smaller than a number of the channel layers 10 that the source/drain features 20 are connected to. In some embodiments, the semiconductor features 104 may be formed even thicker so that the semiconductor features 104 are connected to more than one channel layer 10, and thus the source/drain features 25 are connected to even fewer channel layers 10. In other words, the number of the channel layers that the source/drain features 25 are connected to can be controlled by adjusting the thickness of the semiconductor features 104.

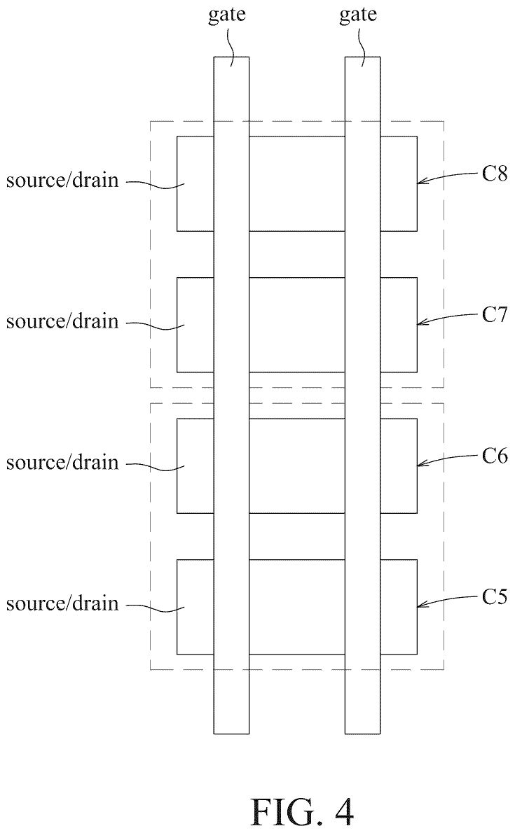

Further referring to FIG. 4, a top view is provided to illustrate an exemplary hybrid cell scheme in terms of effective channel width in accordance with the second embodiment. In FIG. 4, transistor cells C5, C6, C7, C8 have the same physical width (i.e., the source/drain regions have the same width), where the transistor cells C5, C6 are exemplified to have the same sectional structure as illustrated in the left part of FIG. 3, and the transistor cells C7, C8 are exemplified to have the same sectional structure as illustrated in the right part of FIG. 3. Since the source/drain features 25 of the GAA transistors in the transistor cells C7, C8 are connected to fewer channel layers 10 than the source/drain features 20 of the GAA transistors in the transistor cells C5, C6, the effective channel width of the GAA transistors in the transistor cells C7, C8 would be smaller than the effective channel width of the GAA transistors in the transistor cells C5, C6. As a result, transistor cells can be made to have different effective channel width while having the same physical width, and thus process parameters can be optimized for that specific physical width, thereby promoting the production yield and device performance.

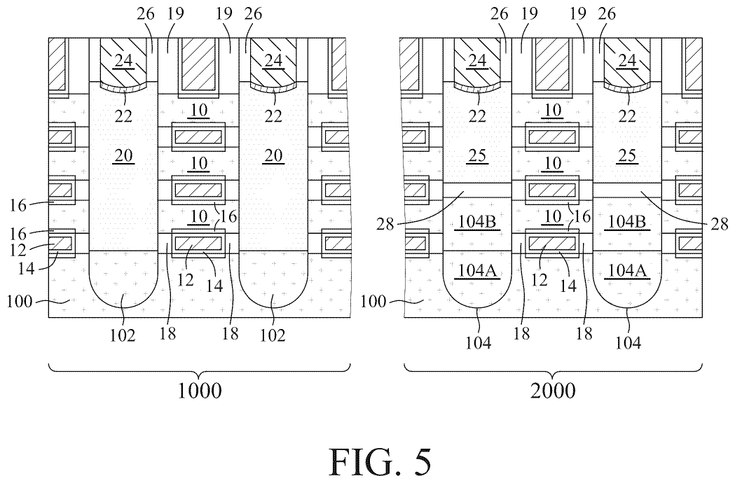

FIG. 5 illustrates sectional views of semiconductor devices formed over a semiconductor substrate 100 in accordance with a third embodiment, where the semiconductor devices are exemplified as p-type GAA transistors, but this disclosure is not limited in this respect. The third embodiment is similar to the second embodiment, and differs in that, in the third embodiment, the second GAA transistor includes isolation layers 28 disposed between the semiconductor features 104 and the source/drain features 25, thereby preventing current leakage from the source/drain features 25 to the semiconductor substrate 100 and the channel layer(s) 10 that are connected to and blocked by the semiconductor features 104. In accordance with some embodiments, the isolation layers 28 may include, for example, silicon nitride, other suitable materials, or any combination thereof.

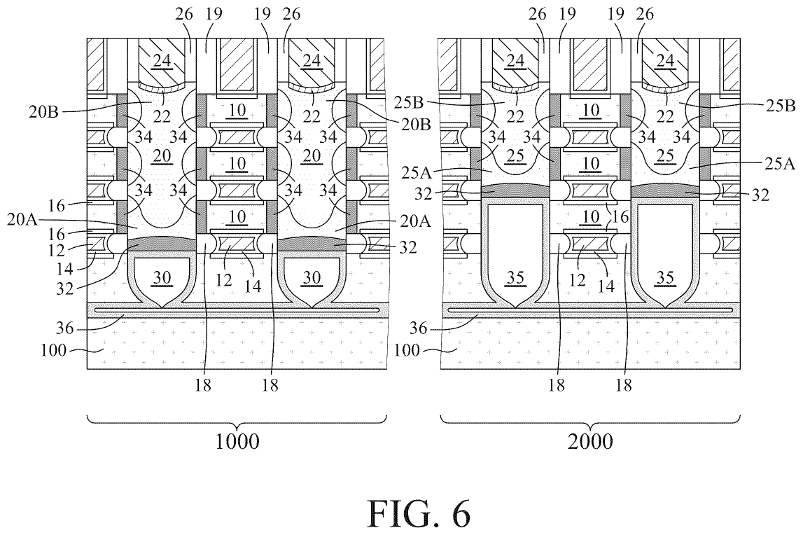

FIG. 6 illustrates sectional views of semiconductor devices formed over a semiconductor substrate 100 in accordance with a fourth embodiment, where the semiconductor devices are exemplified as p-type GAA transistors. The fourth embodiment is similar to the second embodiment, and differences will be described hereinafter. In the fourth embodiment, each of the source/drain features 20, 25 includes a first portion 20A, 25A and a second portion 20B, 25B that include the same chemical elements with different chemical compositions. For example, the first portion 20A, 25A and the second portion 20B, 25B may both include SiGe doped with boron, but have different concentrations of germanium. In accordance with some embodiment, the atomic concentration of germanium in the first portion 20A, 25A may range from about 15% to about 25%, and the atomic concentration of germanium in the second portion 20B, 25B may range from about 50% to about 65%. The first portion 20A, 25A is made to protect the second portion 20B, 25B from being damaged during a subsequent process, and details thereof will be described later. The first GAA transistor (i.e., the GAA transistor in the first circuit region 1000) includes a pair of first air-isolation features 30 disposed respectively under the source/drain features 20, the second GAA transistor (i.e., the GAA transistor in the second circuit region 2000) includes a pair of second air-isolation features 35 disposed respectively under the source/drain features 25, and a dielectric layer 36 is disposed under and in contact with the first air-isolation features 30 and the second air-isolation features 35. In accordance with some embodiments, the first air-isolation features 30 and the second air-isolation features 35 are vacancies filled with air, and take on a funnel shape, which has a wider upper portion and a narrow lower portion. In accordance with some embodiments, the dielectric layer 36 includes, for example, silicon dioxide, a low-k material, other suitable insulator materials, or any combination thereof. In the illustrative embodiment, the dielectric layer 36 extends into the first air-isolation features 30 and the second air-isolation features 35, and are conformally formed on inner walls of the first air-isolation features 30 and the second air-isolation features 35, but this disclosure is not limited in this respect. In some embodiments, the dielectric layer 36 is not formed within the first air-isolation features 30 and/or the second air-isolation features 35.

In the illustrative embodiment, a thickness of the second air-isolation features 35 is greater than a thickness of the first air-isolation features 30, while a thickness from a bottom of one second air-isolation feature 35 to a top of a corresponding source/drain feature 25 is the same as a thickness from a bottom of one first air-isolation feature 30 to a top of a corresponding source/drain feature 20. In alternative embodiments, a height of the second air-isolation features 35 is greater than a height of the first air-isolation features 30, while a height from a bottom of one second air-isolation feature 35 to a top of a corresponding source/drain feature 25 is the same as a height from a bottom of one first air-isolation feature 30 to a top of a corresponding source/drain feature 20. A number of the channel layers 10 of the first GAA transistor that each of the first air-isolation features 30 overlaps in a first channel-length direction (i.e., a lengthwise direction of the channel layers 10 of the first GAA transistor, which is a horizontal direction from the perspective of FIG. 6) is different from a number of the channel layers 10 of the second GAA transistor that each of the second air-isolation features 35 overlaps in a second channel-length direction (i.e., a lengthwise direction of the channel layers 10 of the second GAA transistor, which is the horizontal direction from the perspective of FIG. 6). For example, in FIG. 6, the first air-isolation features 30 overlap none of the channel layers 10 of the first GAA transistor, so the source/drain features 20 are connected to all of the channel layers 10 of the first GAA transistor. On the other hand, the second air-isolation features 35 overlap the bottom one of the channel layers 10 of the second GAA transistor, so the source/drain features 25, which are shorter than the source/drain features 20, are connected to only some of the channel layers 10 of the second GAA transistor. Since the first air-isolation features 30 and the second air-isolation features 35 isolate different numbers of the channel layers 10 from the corresponding source/drain features 20, 25, the first GAA transistor and the second GAA transistor have different effective channel widths. In addition, the first air-isolation features 30 and the second air-isolation features 35 are able to effectively prevent current leakage from upper channel layers 10 that are connected to the source/drain features 20, 25 to the semiconductor substrate 100 as well as the lower channel layers 10 that are not connected to the source/drain features 20, 25.

Each of the first GAA transistor and the second GAA transistor further includes a pair of separation layers 32 and multiple pairs of semiconductor features 34. Each of the separation layers 32 is disposed between a respective one of the source/drain features 20, 25 (i.e., one of the source/drain features 20, 25 that is disposed over the separation layer 32) and the corresponding one of the air-isolation features 30, 35 (i.e., one of the air-isolation features 30, 35 that is disposed under the separation layer 32). The separation layer 32 separates the corresponding source/drain feature 20, 25 from the corresponding air-isolation feature 30, 35, and is configured for protecting the corresponding source/drain feature 20, 25 from being damaged during the process of forming the corresponding air-isolation feature 30, 35. In some embodiment, the pairs of the semiconductor features 34 are formed during a process of forming the separation layers 32, and correspond to the channel layers 10, respectively. In some embodiments, the separation layers 32 and the semiconductor features 34 are made of the same material. In some embodiments, the separation layers 32 and the semiconductor features 34 may include different materials. The semiconductor features 34 in each pair are disposed at opposite sides of the corresponding one of the channel layers 10. In accordance with some embodiments, the separation layer 32 and the semiconductor features 34 may include, for example, SiB (silicon doped with boron), other suitable semiconductor materials, or any combination thereof, so that the semiconductor features 34 do not electrically isolate the channel layers 10 from the corresponding source/drain feature 20, 25, while the separation layers 32 favor the growth of the source/drain features 20, 25. In accordance with some embodiments, the semiconductor features 34 are not formed, and the separation layers 32 may include, for example, silicon nitride, other suitable dielectric materials, or any combination thereof. The first portions 20A, 25A of the source/drain features 20, 25 are formed on the separation layers 32 and the semiconductor features 34. In the illustrative embodiment, for each of the source/drain features 20, 25: the first portion 20A, 25A includes multiple segments that are spaced apart from each other; each of the segments has a curved surface in contact with the corresponding second portion 20B, 25B of the source/drain portion 20, 25, and is connected to at least one of the corresponding separation layer 32 or the corresponding semiconductor features 34; and the second portion 20B, 25B is formed in one piece and is in contact with each of the segments of the first portion 20A, 25A, and is connected to the inner spacers 18. In accordance with some other embodiments (not shown), the first portion 20A, 25A may be formed in one piece as well, and may be connected to each of the corresponding separation layer 32 and the corresponding semiconductor features 34; and the second portion 20B, 25B may be in contact with the first portion 20A, 25A, and may be spaced apart from the inner spacers 18 by the first portion 20A, 25A.

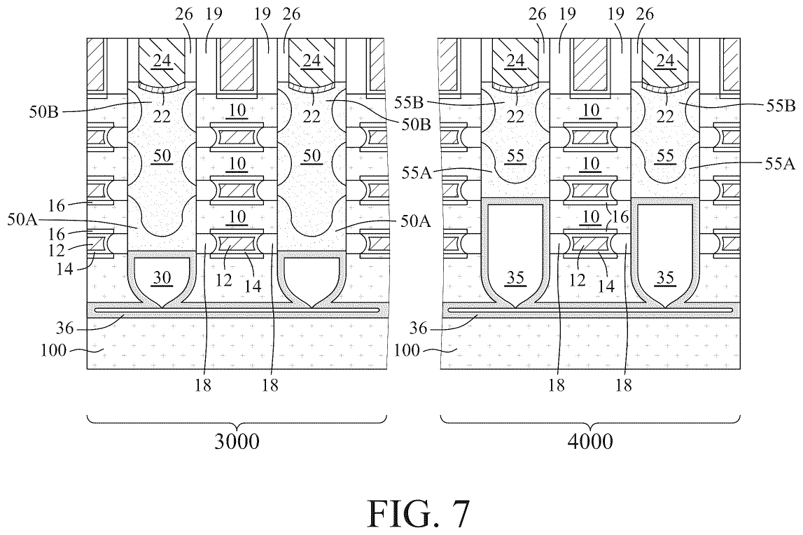

FIG. 7 illustrates sectional views of semiconductor devices formed over a semiconductor substrate 100 in accordance with the fourth embodiment, where the semiconductor devices are exemplified as n-type GAA transistors. The n-type GAA transistors are structurally similar to the p-type GAA transistors (see FIG. 6). For example, the n-type GAA transistor in a third circuit region 3000 (referred to as a third GAA transistor hereinafter) includes a pair of source/drain features 50, the n-type GAA transistors in a fourth circuit region 4000 (referred to as a fourth GAA transistor hereinafter) includes a pair of source/drain features 55, and each of the source/drain features 50, 55 includes a first portion 50A, 55A and a second portion 50B, 55B that are composed of the same chemical elements with different chemical compositions. For example, the first portion 50A, 55A and the second portion 50B, 55B may both include silicon doped with phosphorus, but have different concentrations of phosphorus. In accordance with some embodiments, the concentration of phosphorus in the first portion 50A, 55A may range from about 1E20 cm⁻³ to about 1E21 cm⁻³, and the concentration of phosphorus in the second portion 50B, 55B may range from about 1E21 cm⁻³ to about 5E21 cm⁻³. Such a configuration is used to promote performance of the n-type GAA transistors. The n-type GAA transistors further differ from the p-type GAA transistors in that the n-type GAA transistors do not include the separation layers 32 and the semiconductor features 34. In some embodiments, the separation layers 32 and the semiconductor features 34 are omitted because the material used in the source/drain features 50, 55 of the n-type GAA transistors would not be damaged by the substances used during the process of forming the air-isolation features 30, 35.

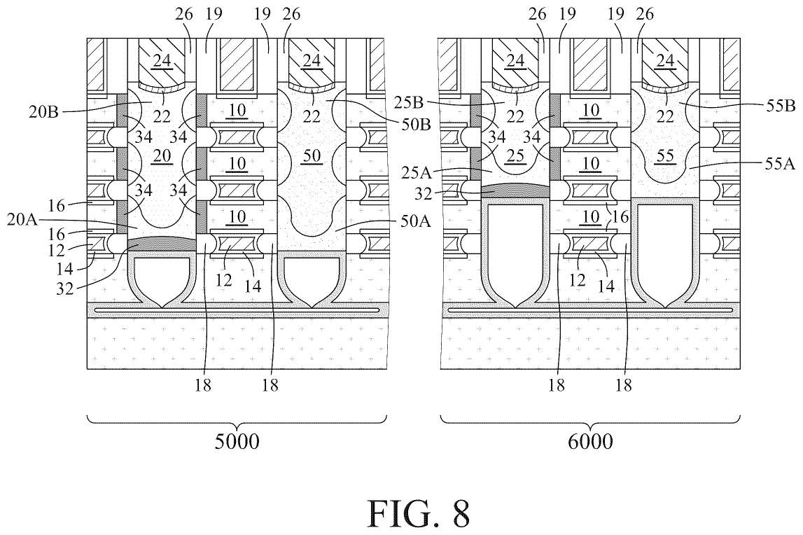

FIG. 8 illustrates sectional views of semiconductor devices formed over a semiconductor substrate 100 in accordance with the fourth embodiment. In some implementations, a p-type source/drain feature (e.g., the aforesaid source/drain feature 20 or 25) and an n-type source/drain feature (e.g., the aforesaid source/drain feature 50 or 55) may be blended in a single semiconductor device.

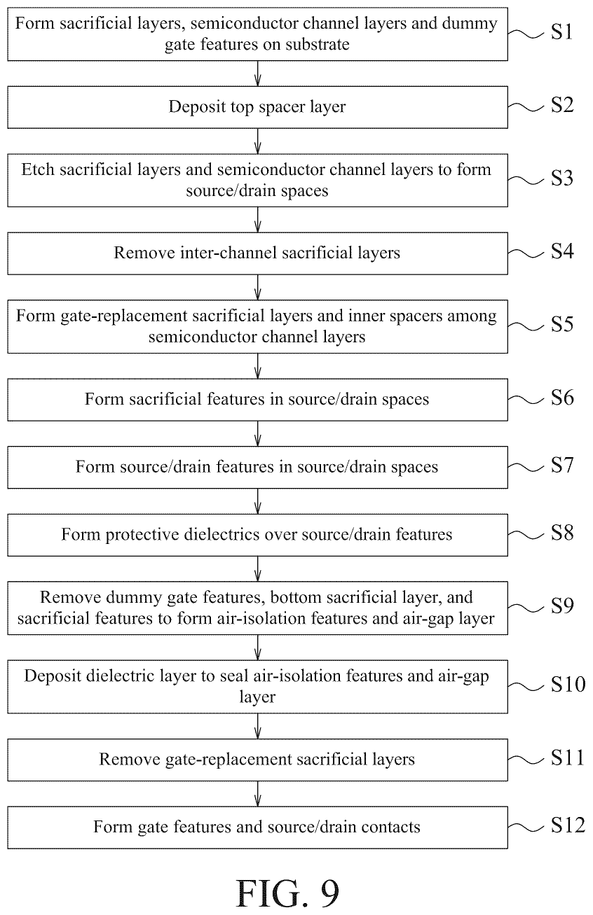

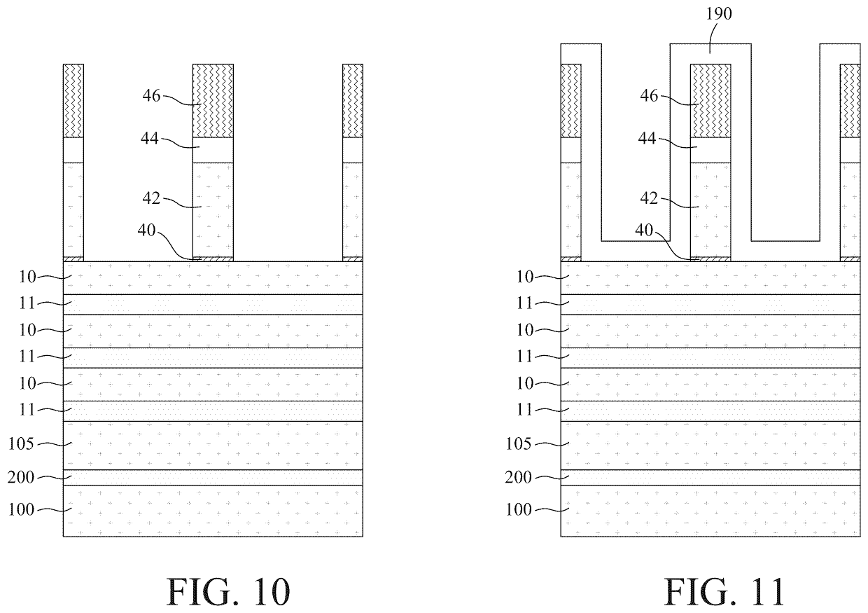

Referring to FIG. 9, a method for fabricating semiconductor devices in accordance with the fourth embodiment is exemplarily provided. Further referring to FIG. 10, in step S1, a stacked feature is formed over the semiconductor substrate 100, and a plurality of dummy gate features are formed over and around the stacked feature. The stacked feature includes a bottom sacrificial layer 200, a semiconductor layer 105 deposited over the bottom sacrificial layer 200, and a plurality of semiconductor channel layers 10 and a plurality of inter-channel sacrificial layers 11 alternately stacked over the semiconductor layer 105. In accordance with some embodiments, the semiconductor layer 105 and the semiconductor channel layers 10 may include, for example, silicon, other suitable materials, or any combination thereof. In accordance with some embodiments, each of the bottom sacrificial layer 200 and the inter-channel sacrificial layers 11 may include, for example, SiGe, other suitable embodiments, or any combination thereof. In accordance with some embodiments, the bottom sacrificial layer 200 and the inter-channel sacrificial layers 11 may have the same combination of chemical elements. In accordance with some embodiments where the bottom sacrificial layer 200 and the inter-channel sacrificial layers 11 include SiGe, an atomic concentration of germanium in these layers may range from about 20% to about 35%. When the atomic concentration of germanium falls within this range, a good balance can be achieved between the difficulty of growing the sacrificial layers 200, 11 and the subsequent difficulty of removing them. Each of the dummy gate features includes an etch stop layer 40 disposed over the top one of the semiconductor channel layers 10, a dummy gate 42 disposed over the etch stop layer 40, a first hard mask 44 disposed over the dummy gate 42, and a second hard mask 46 disposed over the first hard mask 44. In accordance with some embodiments, the etch stop layer 40 may include, for example, SiO₂, SiC, SiN, SiCN, SiOC, SiON, SiCON, other suitable material, or any combination thereof. In accordance with some embodiments, the dummy gate 42 may include, for example, poly-silicon, other suitable materials, or any combination thereof. FIG. 10 shows only a portion of the dummy gate 42 that is disposed over the stacked feature because of the perspective used in FIG. 10, but the dummy gate 42 includes other portions that are connected to lateral sides (e.g., a front side and a rear side from the perspective of FIG. 10) of the stacked feature. In accordance with some embodiments, the first hard mask 44 may include, for example, silicon nitride, other suitable materials, or any combination thereof. In accordance with some embodiments, the second hard mask 46 may include, for example, silicon oxide, other suitable materials, or any combination thereof.

Referring to FIGS. 9 and 11, in step S2, a spacer layer 190 is conformally deposited over the stacked feature and the dummy gate features using, for example, physical vapor deposition (PVD), chemical vapor deposition (CVD), atomic layer deposition (ALD), other suitable techniques, or any combination thereof.

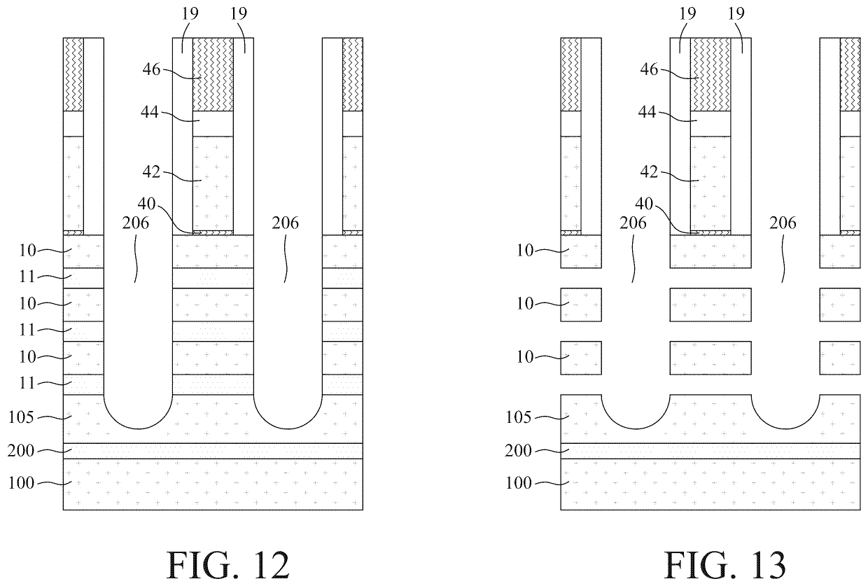

Referring to FIGS. 9 and 12, in step S3, the spacer layer 190, the semiconductor channel layers 10 and the inter-channel sacrificial layers 11 are etched using, for example, an anisotropic etching, thereby forming a plurality of source/drain spaces (or recesses) 206. The remaining portions of the spacer layer 190 form top spacers 19, and the remaining portions of the semiconductor channel layers 10 and the inter-channel sacrificial layers 11 form a plurality of fin features respectively under the dummy gate features. For each of the fin features, there are two adjacent source/drain spaces 206 disposed respectively at opposite sides of the fin feature. Therefore, each of the fin features can be deemed as including multiple semiconductor channel layers 10 and multiple inter-channel sacrificial layers 11 that are alternately stacked together. It is noted that the semiconductor layer 105 is only partially etched away in step S3, so the bottom sacrificial layer 200 is still buried under the semiconductor layer 105 and is not revealed on the source/drain spaces 206.

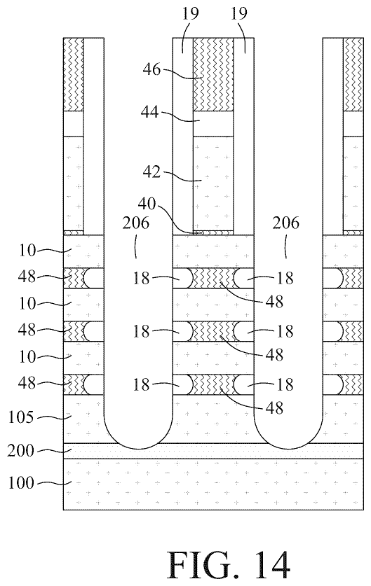

Referring to FIGS. 9 and 13, in step S4, the inter-channel sacrificial layers 11 (see FIG. 12) are removed from the fin features using, for example, dry etching, wet etching, other suitable etching techniques, or any combination thereof.

Referring to FIGS. 9 and 14, in step S5, multiple placeholder layers 48 and multiple pairs of inner spacers 18 are formed among the semiconductor channel layers 10. In other words, the inter-channel sacrificial layers 11 (see FIG. 12) are replaced by the placeholder layers 48 and the inner spacers 18, resulting in fin features being composed of the semiconductor channel layers 10, the placeholder layers 48 and the inner spacers 18 in this step. In accordance with some embodiments, the placeholder layers 48 may include chemical elements that are different from the bottom sacrificial layer 200, such as silicon oxide, other oxide, a nitride material, other suitable materials, or any combination thereof, as long as the material used in the placeholder layers 48 has good resistance against an etchant that is used to etch the bottom sacrificial layer 200 in a later process step. The pairs of the inner spacers 18 respectively correspond to the placeholder layers 48, and the inner spacers 18 in each pair are formed at opposite sides of the corresponding one of the placeholder layers 48. In practice, in step S5, the placeholder layers 48 are first deposited to fill the spaces among the semiconductor channel layers 10; and then, an isotropic etching is performed to etch the placeholder layers 48 from lateral sides, thereby creating spaces at opposite sides of the placeholder layers 48 among the semiconductor channel layers 10. Subsequently, the inner spacers 18 are deposited to fill the spaces thus created, followed by an etching process to remove redundant spacer materials that are formed outside of the fin features. It is noted that the semiconductor layer 105 is also etched during the etching of the placeholder layers 48 and the etching of the inner spacer materials, so the bottom sacrificial layer 200 is partially exposed from the source/drain spaces 206.

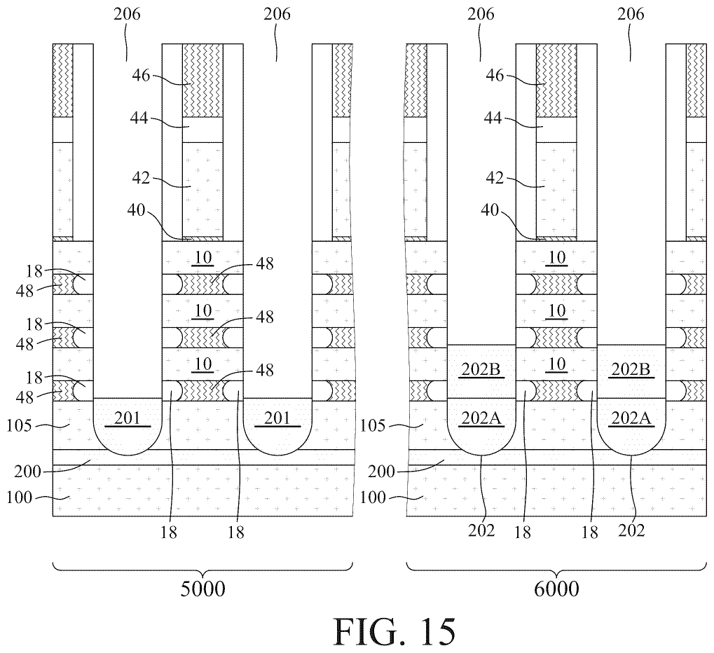

Referring to FIGS. 9 and 15, in step S6, multiple sacrificial features are formed in the source/drain spaces 206 and over the bottom sacrificial layer 200. In order to illustrate the hybrid cell scheme in accordance with the fourth embodiment, FIG. 15 shows a first cell region 5000 and a second cell region 6000, where the GAA transistor to be formed in the first cell region 5000 has a greater effective channel width than the GAA transistor to be formed in the second cell region 6000. In FIG. 15, the structures in the first cell region 5000 and the second cell region 6000 may be formed simultaneously on the semiconductor substrate 100 through the aforesaid steps S1 through S5, so the fin features in the first cell region 5000 (referred to first fin features herein after) and the fin features in the second cell region 6000 (referred to second fin features hereinafter) have the same thickness and the same number of the semiconductor channel layers 10, and the semiconductor channel layers 10 of each first fin feature respectively correspond to the semiconductor channel layers 10 of each second fin feature in terms of height relative to the surface of the semiconductor substrate 100. In accordance with some embodiments, a width of the first fin feature in a first channel-width direction, which is the channel-width direction of the semiconductor channel layers 10 of the first fin feature, is the same as a width of the second fin feature in a second channel-width direction, which is a channel-width direction of the semiconductor channel layers 10 of the second fin feature, but this disclosure is not limited in this respect.

The sacrificial features include first sacrificial features 201 that are respectively formed in the source/drain spaces 206 in the first cell region 5000, and second sacrificial features 202 that are respectively formed in the source/drain spaces 206 in the second cell region 6000. Each of the first sacrificial features 201 and the second sacrificial features 202 is connected to the exposed parts of the bottom sacrificial layer 200. A number of the semiconductor channel layers 10 of the first fin feature that each of the first sacrificial features 201 overlaps in a first channel-length direction, which is the channel-length direction of the semiconductor channel layers 10 of the first fin feature, is different from a number of the semiconductor channel layers 10 of the second fin feature that each of the second sacrificial features 202 overlaps in a second channel-length direction, which is the channel-length direction of the semiconductor channel layers 10 of the second fin feature. In the illustrative embodiment, the second sacrificial features 202 are thicker than the first sacrificial features 201, and overlap and are connected to more semiconductor channel layers 10 than the first sacrificial features 201. Each of the second sacrificial features 202 includes a first portion 202A that is as thick as the first sacrificial features 201, and a second portion 202B that is disposed over and connected to the first portion 202A. In accordance with some embodiments, the first sacrificial features 201 and the first portions 202A of the second sacrificial features 202 are deposited first simultaneously. Then, the first cell region 5000 would be masked using, for example, an AlO layer, an AlN layer, a layer of other suitable materials, or any combination thereof, and the second portions 202B of the second sacrificial features 202 are deposited over the first portions 202A. In accordance with some embodiments, the first sacrificial features 201 and the second sacrificial features 202 include the same chemical elements as the bottom sacrificial layer 200.

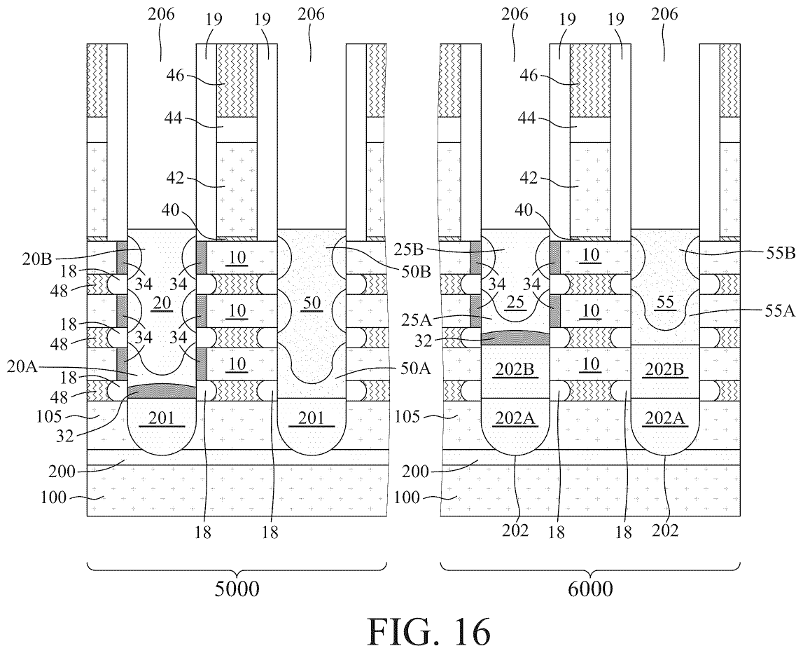

Referring to FIGS. 9 and 16, in step S7, source/drain features are respectively formed in the source/drain spaces 206. The source/drain features are classified into first source/drain features that are formed in the source/drain spaces 206 in the first cell region 5000, and second source/drain features that are formed in the source/drain spaces 206 in the second cell region 6000. For ease of illustration, in FIG. 16, the first source/drain features are respectively drawn as a p-type source/drain feature 20 and an n-type source/drain feature 50, and the second source/drain features are respectively drawn as a p-type source/drain feature 25 and an n-type source/drain feature 55, but this disclosure is not limited in this respect. In accordance with some embodiments, both of the first source/drain features may be of the same type, and both of the second source/drain features may be of the same type. In step S7, when the process proceeds to form the source/drain features 20, 25, regions where the source/drain features 50, 55 are to be formed or have been formed would be masked using, for example, a photoresist layer, a dielectric layer, a layer of other suitable materials, or any combination thereof. Likewise, when the process proceeds to form the source/drain features 50, 55, regions where the source/drain features 20, 25 are to be formed or have been formed would be masked using, for example, a photoresist layer, a dielectric layer, a layer of other suitable materials, or any combination thereof. In accordance with some embodiments, the source/drain features 20, 25, 50, 55 may be formed using, for example, epitaxy processes, other suitable techniques, or any combination thereof. During the process of forming the source/drain features 20, 25 or the source/drain features 50, 55, the first portions 20A, 25A, 50A, 55A may be formed first, followed by forming the second portions 20B, 25B, 50B, 55B. In accordance with some embodiments, top surfaces of the source/drain features 20, 25 may be formed to be at the same height, and top surfaces of the source/drain features 50, 55 may be formed to be at the same height, but this disclosure is not limited in this respect. In accordance with some embodiments, before the process of forming the source/drain features 20, 25, separation layers 32 are formed respectively over the corresponding sacrificial features 201, 202, and the semiconductor features 34 are formed on the semiconductor channel layers 10 in the same process. In the illustrative embodiment, the separation layers 32 are made of a semiconductor material (e.g., SiB) whose lattice structure matches a lattice structure of the source/drain features 20, 25 (e.g., SiGe), so the source/drain features 20, 25 can be grown in a bottom-up manner, thereby resulting in good epitaxial strain of the source/drain features 20, 25, which may lead to good direct current (DC) performance of the GAA transistor.

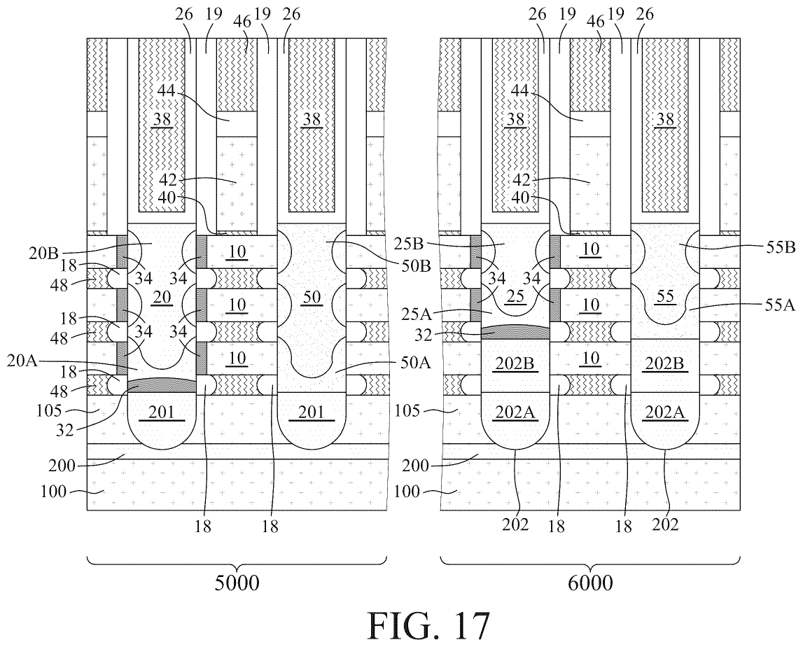

Referring to FIGS. 9 and 17, in step S8, a dielectric layer 26 is conformally deposited in each of the source/drain spaces 206 (see FIG. 16), and then a dielectric feature 38 is deposited to fill up the source/drain space 206. In accordance with some embodiments, the dielectric feature 38 may include, for example, silicon dioxide, other suitable materials, or any combination thereof. The dielectric layer 26 can be a contact etch stop layer (CESL). In some embodiment, the material of CESL can be SiN.

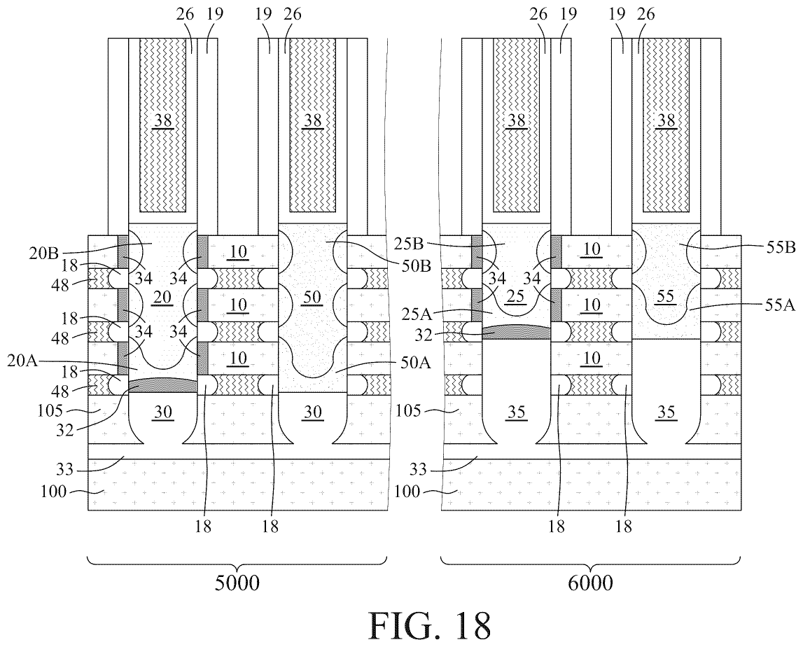

Referring to FIGS. 9 and 18, in step S9, the dummy gate features are removed to expose a part of the bottom sacrificial layer 200 (see FIG. 17) that is directly below the dummy gate feature and that was originally covered by the dummy gate 42 (see FIG. 17) on the lateral sides (i.e., the front and rear sides from the perspective of FIG. 17), and then the bottom sacrificial layer 200 and the sacrificial features 201, 202 (see FIG. 17) are removed through the exposed part of the bottom sacrificial layer 200, thereby forming air-isolation features 30, 35 respectively under the source/drain features 20, 25, 50, 55, and an air-gap layer 33 under and in spatial communication with the air-isolation features 30, 35. The separation layers 32 are configured to have better resistance (compared to the bottom sacrificial layer 200 and the sacrificial features 201, 202) against an etchant used in the process of removing the bottom sacrificial layer 200 and the sacrificial features 201, 202, thereby protecting the source/drain features 20, 25, which may include the same combination of chemical elements as the sacrificial features 201, 202, from being removed during the process of forming the air-isolation features 30, 35. The first portions 20A, 25A of the source/drain features 20, 25 provide further protection for the second portions 20B, 25B during the process of removing the sacrificial features 201, 202 in case the separation layers 32 do not provide sufficient protection. As an example, in a case where the source/drain features 20, 25 are made of SiGe doped with boron and the sacrificial features 201, 202 are made of SiGe, the lower concentration of germanium in the first portions 20A, 25A of the source/drain features 20, 25 can have higher resistance against an etchant used to remove the sacrificial features 201, 202 when compared to the second portions 20B, 25B of the source/drain features 20. 25.

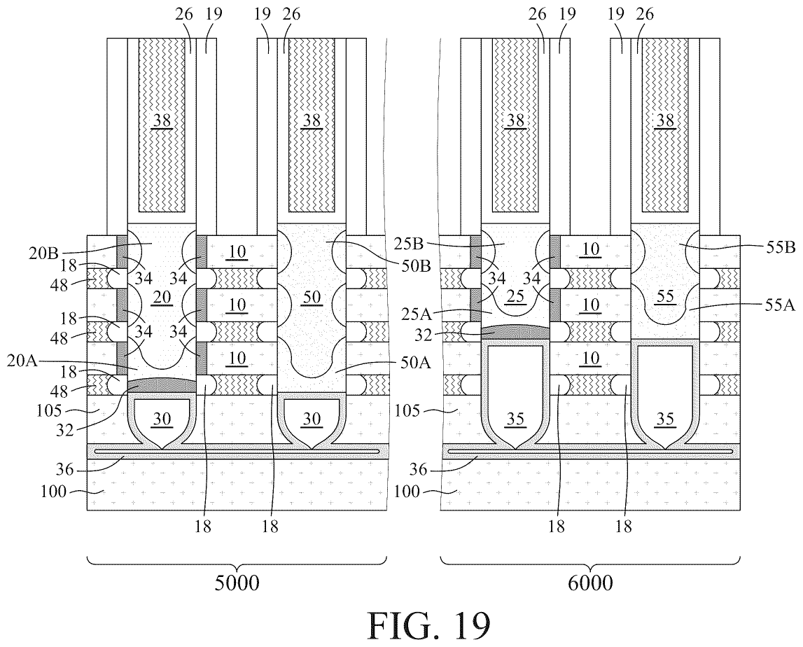

Referring to FIGS. 9 and 19, in step S10, a dielectric layer 36 is deposited into part of the air-gap layer 33 (see FIG. 18) that is exposed from a space created after the removal of the dummy gate features (i.e., corresponding in position to the part of the bottom sacrificial layer 200 exposed in step S9), thereby sealing the air-isolation features 30, 35 and the air-gap layer 33. In accordance with some embodiments, during the deposition process, the dielectric layer 36 may be conformally formed on inner walls of the air-isolation features 30, 35 and the air-gap layer 33 before the exposed part of the air-gap layer 33 is completely filled. In accordance with some embodiments, during the deposition process, the dielectric layer 36 may be conformally formed only on inner walls of the air-gap layer 33 but not on inner walls of the air-isolation features 30, 35 before the exposed part of the air-gap layer 33 is completely filled. In accordance with some embodiments, the dielectric layer 36 completely fills the exposed part of the air-gap layer 33, but is not formed in either the air-isolation features 30, 35 or other portions of the air-gap layer 33. In accordance with some embodiments, the dielectric layer 36 is deposited using, for example, CVD, ALD, other suitable techniques, or any combination thereof.

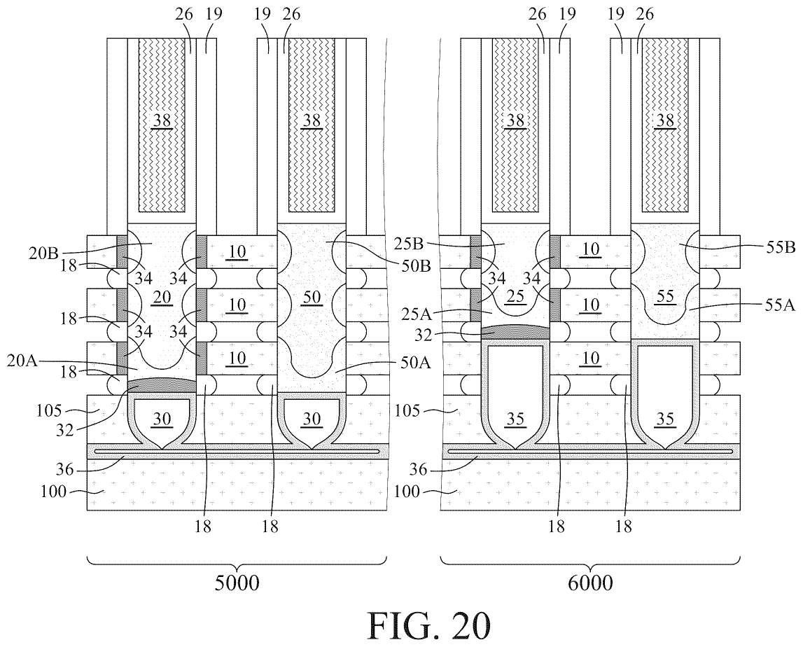

Referring to FIGS. 9 and 20, in step S11, the placeholder layers 48 (see FIG. 19) are removed using, for example, wet etching, dry etching, other suitable techniques, or any combination thereof.

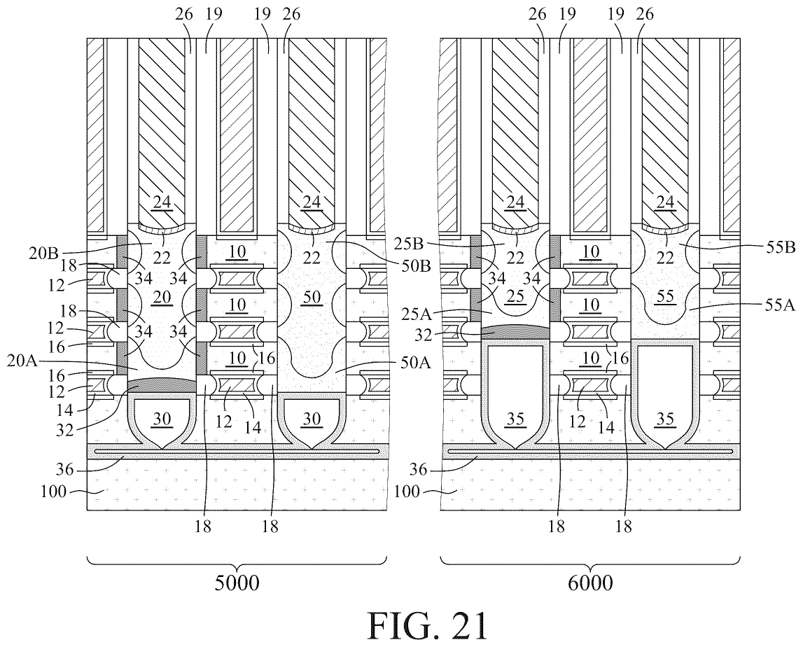

Referring to FIGS. 9 and 21, in step S12, gate features (each including a gate electrode 12, a gate dielectric 14, etc.) are formed in the spaces that were created by removing the placeholder layers 48 (see FIG. 20) in step S11 (namely, the placeholder layers 48 are replaced by the gate features), followed by removing the dielectric features 38 (see FIG. 20) and forming source/drain contacts 24.

In accordance with some embodiments, a method for fabricating a semiconductor device is provided. In one step, a first sacrificial layer is formed over a semiconductor substrate. In one step, a first fin feature and first source/drain spaces are formed over the first sacrificial layer, where the first fin feature includes a first channel feature, and the first source/drain spaces are adjacent to the first fin feature. In one step, a part of the first sacrificial layer is exposed in each of the first source/drain spaces. In one step, first sacrificial features are formed in the first source/drain spaces, where the first sacrificial features are connected to the parts of the first sacrificial layer that are exposed in the first source/drain spaces. In one step, first source/drain features are formed over the first sacrificial features in the first source/drain spaces. In one step, the first sacrificial layer and the first sacrificial features are removed to form first air-isolation features under the first source/drain features, and an air-gap layer in spatial communication with and under the first air-isolation features. In one step, a first gate feature is formed in the first fin feature.

In accordance with some embodiments, in one step, a dielectric layer that seals the air-gap layer is deposited.

In accordance with some embodiments, in one step, a dummy gate feature is formed around the first fin feature during the forming of the first fin feature and the first source/drain spaces. In one step, the dummy gate feature is formed after the forming of the first source/drain features, thereby exposing another part of the first sacrificial layer for removing the first sacrificial layer and the first sacrificial features.

In accordance with some embodiments, in one step, a separation layer is formed over the first sacrificial features in the first source/drain spaces. The first source/drain features are formed over the separation layer. The separation layer has a higher etching resistance against an etchant used in the removal of the first sacrificial layer and the first sacrificial features than the first source/drain features, thereby protecting the first source/drain features from being removed during the removal of the first sacrificial layer and the first sacrificial features.

In accordance with some embodiments, in one step, a second fin feature and second source/drain spaces are formed over the first sacrificial layer, where the second fin feature includes a second channel feature, and the second source/drain spaces are adjacent to the second fin feature. In one step, a part of the first sacrificial layer is exposed in each of the second source/drain spaces. In one step, second sacrificial features are formed in the second source/drain spaces, where the second sacrificial features are connected to the parts of the first sacrificial layer that are exposed in the second source/drain spaces, and have a thickness different from a thickness of the first sacrificial features. In one step, second source/drain features are formed over the second sacrificial features in the second source/drain spaces. In one step, the second sacrificial features are removed to form second air-isolation features under the second source/drain features, where the second air-isolation features are in spatial communication with and over the air-gap layer. In one step, a second gate feature is formed in the second fin feature.

In accordance with some embodiments, the second sacrificial features are removed during the removal of the first sacrificial layer and the first sacrificial features.

In accordance with some embodiments, the first channel feature includes first channel layers that are spaced apart from each other, and the second channel feature includes second channel layers that are spaced apart from each other and that correspond in position to the first channel layers, respectively. Each of the first sacrificial features is formed to overlap a first number of the first channel layers in a channel-length direction of the first channel feature, each of the second sacrificial features is formed to overlap a second number of the second channel layers in a channel-length direction of the second channel feature, and the first number is different from the second number.

In accordance with some embodiments, the first fin feature and the second fin feature have a same thickness.

In accordance with some embodiments, a width of the first fin feature in a channel-width direction of the first channel feature is same as a width of the second fin feature in a channel-width direction of the second channel feature.

In accordance with some embodiments, each of the second sacrificial features includes a first portion that is as thick as the first sacrificial features, and a second portion disposed over the first portion. The forming of second sacrificial features in the second source/drain spaces includes the following actions. In one action, the first portions of the second sacrificial features are formed during the forming of the first sacrificial features. In one action, the first sacrificial features are masked. In one action, the second portions of the second sacrificial features are formed over the first portions of the second sacrificial features with the first sacrificial features being masked.

In accordance with some embodiments, the first channel feature includes multiple first channel layers, and, before exposing the part of the first sacrificial layer in each of the first source/drain spaces, the first fin feature is formed to include multiple placeholder layers that are alternately stacked with the first channel layers. The multiple placeholder layers and the first sacrificial layers include different chemical elements.

In accordance with some embodiments, the first fin feature is formed to include multiple first inter-channel sacrificial layers that are alternately stacked with the first channel layers during the forming of the first fin feature and the first source/drain spaces over the first sacrificial layer, and the multiple first inter-channel sacrificial layers and the first sacrificial layer have a same combination of chemical elements. In one step before exposing the part of the first sacrificial layer in each of the first source/drain spaces, the multiple first inter-channel sacrificial layers are replaced with the placeholder layers, respectively.

In accordance with some embodiments, a method for fabricating a semiconductor device is provided. In one step, a stacked feature is formed over a semiconductor substrate, where the stacked feature includes a first sacrificial layer, semiconductor channel layers, and inter-channel sacrificial layers. The semiconductor channel layers and inter-channel sacrificial layers are formed over the first sacrificial layer, and are alternately stacked together. In one step, dummy gate features are formed over and around the stacked feature. In one step, the semiconductor channel layers and the inter-channel sacrificial layers are etched to form a first fin feature and first source/drain spaces over the first sacrificial layer, where the first fin feature includes a first portion of the semiconductor channel layers and a first portion of the inter-channel sacrificial layers, and the first source/drain spaces are adjacent to the first fin feature. In one step, a part of the first sacrificial layer is revealed in each of the first source/drain spaces. In one step, first sacrificial features are formed in the first source/drain spaces, where the first sacrificial features are connected to the parts of the first sacrificial layer that are revealed in the first source/drain spaces. In one step, first source/drain features are formed over the first sacrificial features in the first source/drain spaces. In one step, the first sacrificial layer and the first sacrificial features are removed to form first air-isolation features under the first source/drain features, and an air-gap layer in spatial communication with and under the first air-isolation features. In one step, a first gate feature is formed in the first fin feature.

In accordance with some embodiments, after etching the semiconductor channel layers and the inter-channel sacrificial layers and before revealing the first sacrificial layer from the first source/drain spaces, the first portion of the inter-channel sacrificial layers is removed from the first fin feature. In one step after removing the inter-channel sacrificial layers from the first fin feature, placeholder layers are formed among the first portion of the semiconductor channel layers of the first fin feature.

In accordance with some embodiments, the removal of the first sacrificial layer and the first sacrificial features includes the following actions. In one action, the dummy gate features are removed to reveal another part of the first sacrificial layer. In one action, etching is performed on the first sacrificial layer and the first sacrificial features through the another part of the first sacrificial layer thus revealed.

In accordance with some embodiments, in one step, a dielectric material that seals the air-gap layer is deposited.

In accordance with some embodiments, the etching of the semiconductor channel layers and the inter-channel sacrificial layers further forms a second fin feature and second source/drain spaces over the first sacrificial layer, where the second fin feature includes a second portion of the semiconductor channel layers and a second portion of the inter-channel sacrificial layers, and the second source/drain spaces are adjacent to the second fin feature. In one step, a part of the first sacrificial layer is revealed in each of the second source/drain spaces. In one step, second sacrificial features are formed in the second source/drain spaces, where the second sacrificial features are connected to the parts of the first sacrificial layer that are revealed in the second source/drain spaces, and have a thickness different from a thickness of the first sacrificial features. In one step, second source/drain features are formed over the second sacrificial features in the second source/drain spaces. In one step, a second gate feature is formed in the second fin feature. The second sacrificial features are removed during the removal of the first sacrificial layer and the first sacrificial features, thereby forming second air-isolation features under the second source/drain features, where the second air-isolation features are in spatial communication with and over the air-gap layer.

In accordance with some embodiments, each of the first sacrificial features is formed to overlap a first number of the semiconductor channel layers in the first portion of the semiconductor channel layers, and each of the second sacrificial features is formed to overlap a second number of the semiconductor channel layers in the second portion of the semiconductor channel layers, and the first number is different from the second number.

In accordance with some embodiments, a semiconductor device is provided to include a substrate, a first stack of semiconductor sheets disposed over the substrate, a first gate feature surrounding each of the semiconductor sheets in the first stack, first source/drain features disposed adjacent and connected to a first number of the semiconductor sheets in the first stack, and first air-isolation features disposed under the first source/drain features.

In accordance with some embodiments, the semiconductor device further includes a second stack of semiconductor sheets disposed over the substrate, a second gate feature surrounding each of the semiconductor sheets in the second stack, second source/drain features disposed adjacent and connected to a second number of the semiconductor sheets in the second stack, and second air-isolation features disposed under the second source/drain features. A total number of the semiconductor sheets in the second stack is identical to a total number of the semiconductor sheets in the first stack. The first number is different from the second number.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor device, comprising:
forming a first sacrificial layer over a semiconductor substrate;
forming a first fin feature and first source/drain spaces over the first sacrificial layer, where the first fin feature includes a first channel feature, and the first source/drain spaces are adjacent to the first fin feature;
exposing a part of the first sacrificial layer in each of the first source/drain spaces;
forming first sacrificial features in the first source/drain spaces, where the first sacrificial features are connected to the parts of the first sacrificial layer that are exposed in the first source/drain spaces;
forming first source/drain features over the first sacrificial features in the first source/drain spaces;
removing the first sacrificial layer and the first sacrificial features to form first air-isolation features under the first source/drain features, and an air-gap layer in spatial communication with and under the first air-isolation features; and
forming a first gate feature in the first fin feature.

2. The method according to claim 1, further comprising depositing a dielectric layer that seals the air-gap layer.

3. The method according to claim 1, further comprising:
forming a dummy gate feature around the first fin feature during the forming of the first fin feature and the first source/drain spaces; and
removing the dummy gate feature after the forming of the first source/drain features, thereby exposing another part of the first sacrificial layer for removing the first sacrificial layer and the first sacrificial features.

4. The method according to claim 1, further comprising forming a separation layer over the first sacrificial features in the first source/drain spaces;
wherein the first source/drain features are formed over the separation layer; and
wherein the separation layer has a higher etching resistance against an etchant used in the removal of the first sacrificial layer and the first sacrificial features than the first source/drain features, thereby protecting the first source/drain features from being removed during the removal of the first sacrificial layer and the first sacrificial features.

5. The method according to claim 1, further comprising:
forming a second fin feature and second source/drain spaces over the first sacrificial layer, where the second fin feature includes a second channel feature, and the second source/drain spaces are adjacent to the second fin feature;
exposing a part of the first sacrificial layer in each of the second source/drain spaces;
forming second sacrificial features in the second source/drain spaces, where the second sacrificial features are connected to the parts of the first sacrificial layer that are exposed in the second source/drain spaces, and have a thickness different from a thickness of the first sacrificial features;
forming second source/drain features over the second sacrificial features in the second source/drain spaces;
removing the second sacrificial features to form second air-isolation features under the second source/drain features, where the second air-isolation features are in spatial communication with and over the air-gap layer; and
forming a second gate feature in the second fin feature.

6. The method according to claim 5, wherein the second sacrificial features are removed during the removal of the first sacrificial layer and the first sacrificial features.

7. The method according to claim 5, wherein the first channel feature includes first channel layers that are spaced apart from each other, and the second channel feature includes second channel layers that are spaced apart from each other and that correspond in position to the first channel layers, respectively; and
wherein each of the first sacrificial features is formed to overlap a first number of the first channel layers in a channel-length direction of the first channel feature, each of the second sacrificial features is formed to overlap a second number of the second channel layers in a channel-length direction of the second channel feature, and the first number is different from the second number.

8. The method according to claim 7, wherein the first fin feature and the second fin feature have a same thickness.

9. The method according to claim 8, wherein a width of the first fin feature in a channel-width direction of the first channel feature is same as a width of the second fin feature in a channel-width direction of the second channel feature.

10. The method according to claim 5, wherein each of the second sacrificial features includes a first portion that is as thick as the first sacrificial features, and a second portion disposed over the first portion; and
wherein the forming of second sacrificial features in the second source/drain spaces includes:
forming the first portions of the second sacrificial features during the forming of the first sacrificial features;
masking the first sacrificial features; and
forming the second portions of the second sacrificial features over the first portions of the second sacrificial features with the first sacrificial features being masked.

11. The method according to claim 1, wherein the first channel feature includes multiple first channel layers, and, before exposing the part of the first sacrificial layer in each of the first source/drain spaces, the first fin feature is formed to include multiple placeholder layers that are alternately stacked with the first channel layers; and
wherein the multiple placeholder layers and the first sacrificial layers include different chemical elements.

12. The method according to claim 11, wherein the first fin feature is formed to include multiple first inter-channel sacrificial layers that are alternately stacked with the first channel layers during the forming of the first fin feature and the first source/drain spaces over the first sacrificial layer, and the multiple first inter-channel sacrificial layers and the first sacrificial layer have a same combination of chemical elements; and
wherein the method further comprises, before exposing the part of the first sacrificial layer in each of the first source/drain spaces, replacing the multiple first inter-channel sacrificial layers with the placeholder layers, respectively.

13. A method for fabricating a semiconductor device, comprising:
forming a stacked feature over a semiconductor substrate, where the stacked feature includes a first sacrificial layer, semiconductor channel layers, and inter-channel sacrificial layers, the semiconductor channel layers and inter-channel sacrificial layers being formed over the first sacrificial layer, and being alternately stacked together;
forming dummy gate features over and around the stacked feature;
etching the semiconductor channel layers and the inter-channel sacrificial layers to form a first fin feature and first source/drain spaces over the first sacrificial layer, where the first fin feature includes a first portion of the semiconductor channel layers and a first portion of the inter-channel sacrificial layers, and the first source/drain spaces are adjacent to the first fin feature;
revealing a part of the first sacrificial layer in each of the first source/drain spaces;
forming first sacrificial features in the first source/drain spaces, where the first sacrificial features are connected to the parts of the first sacrificial layer that are revealed in the first source/drain spaces;
forming first source/drain features over the first sacrificial features in the first source/drain spaces;
removing the first sacrificial layer and the first sacrificial features to form first air-isolation features under the first source/drain features, and an air-gap layer in spatial communication with and under the first air-isolation features; and
forming a first gate feature in the first fin feature.

14. The method according to claim 13, further comprising, after etching the semiconductor channel layers and the inter-channel sacrificial layers and before revealing the first sacrificial layer from the first source/drain spaces:
removing the first portion of the inter-channel sacrificial layers from the first fin feature;
wherein said method further comprises, after removing the inter-channel sacrificial layers from the first fin feature:
forming placeholder layers among the first portion of the semiconductor channel layers of the first fin feature.

15. The method according to claim 13, wherein the removal of the first sacrificial layer and the first sacrificial features includes:
removing the dummy gate features to reveal another part of the first sacrificial layer; and
performing etching on the first sacrificial layer and the first sacrificial features through the another part of the first sacrificial layer thus revealed.

16. The method according to claim 13, further comprising depositing a dielectric material that seals the air-gap layer.

17. The method according to claim 13, wherein the etching of the semiconductor channel layers and the inter-channel sacrificial layers further forms a second fin feature and second source/drain spaces over the first sacrificial layer, where the second fin feature includes a second portion of the semiconductor channel layers and a second portion of the inter-channel sacrificial layers, and the second source/drain spaces are adjacent to the second fin feature;
wherein said method further comprises:
revealing a part of the first sacrificial layer in each of the second source/drain spaces;
forming second sacrificial features in the second source/drain spaces, where the second sacrificial features are connected to the parts of the first sacrificial layer that are revealed in the second source/drain spaces, and have a thickness different from a thickness of the first sacrificial features;
forming second source/drain features over the second sacrificial features in the second source/drain spaces; and
forming a second gate feature in the second fin feature,
wherein the second sacrificial features are removed during the removal of the first sacrificial layer and the first sacrificial features, thereby forming second air-isolation features under the second source/drain features, where the second air-isolation features are in spatial communication with and over the air-gap layer.

18. The method according to claim 17, wherein each of the first sacrificial features is formed to overlap a first number of the semiconductor channel layers in the first portion of the semiconductor channel layers, and each of the second sacrificial features is formed to overlap a second number of the semiconductor channel layers in the second portion of the semiconductor channel layers, and the first number is different from the second number.

19. A semiconductor device, comprising:
a substrate;
a first stack of semiconductor sheets disposed over the substrate;
a first gate feature surrounding each of the semiconductor sheets in the first stack;
first source/drain features disposed adjacent and connected to a first number of the semiconductor sheets in the first stack; and
first air-isolation features disposed under the first source/drain features.

20. The semiconductor device according to claim 19, further comprising:
a second stack of semiconductor sheets disposed over the substrate;
a second gate feature surrounding each of the semiconductor sheets in the second stack, where a total number of the semiconductor sheets in the second stack is identical to a total number of the semiconductor sheets in the first stack;
second source/drain features disposed adjacent and connected to a second number of the semiconductor sheets in the second stack, where the first number is different from the second number; and
second air-isolation features disposed under the second source/drain features.
